(19) United States
(12) Patent Application Publication
(10) Pub. No.: US 2014/0224302 A1
(43) Pub. Date: Aug. 14, 2014

(54) PHOTOVOLTAIC DEVICES WITH AN IMPROVED THERMAL MANAGEMENT FEATURES

(71) Applicant: DOW GLOBAL TECHNOLOGIES LLC, Midland, MI (US)

(72) Inventors: James R Keenihan, Midland, MI (US); Leonardo Lopez, Midland, MI (US)

(21) Appl. No.: 14/342,413

(22) PCT Filed: Sep. 19, 2012
(86) PCT No.: PCT/US12/55972

§ 371 Date: Mar. 3, 2014

Related U.S. Application Data
(60) Provisional application No. 61/537,628, filed on Sep. 22, 2011.

(51) Int. Cl. H01L 31/052

(52) U.S. Cl. CPC H01L 31/0521
USPC 136/246; 136/259

(57) ABSTRACT

The present invention is premised upon a photovoltaic device for use on a structure, The device having a. an inactive portion including lower surface portion that directly or indirectly contacts the structure, and an upper surface portion that includes one or more open airflow conduits and a fastener region for receiving one or more fasteners capable of securing the photovoltaic device directly to the structure; and b. an active portion including a photovoltaic cell assembly; wherein the active portion and the inactive portion are coupled on at least one peripheral edge and the one or more conduit structures In the upper surface portion of the inactive portion is in fluid communication with a portion of a bottom surface of the active portion.

### CLAIM OF PRIORITY

The present application claims the benefit of the filing date of U.S. Provisional Application No. 61/537,628 filed on Sep. 22, 2011 the contents of which are hereby incorporated by reference in theft entirety.

### FIELD OF THE INVENTION

The present invention relates to photovoltaic devices that include improved thermal management features, more particularly to at least conduit features created between first and second photovoltaic devices.

### BACKGROUND

Efforts to improve PV devices, particularly those devices that are integrated into building, structures (e.g. photovoltaic sheathing elements, spacer pieces, edge pieces), to be used successfully, should satisfy a number of criteria. The PV devices may be commonly known as Building-integrated photovoltaics (BIPV). These BIPVs are typically PV devices (and associated system components) that are used to replace conventional building materials in parts of the building envelope such as the roof, skylights, or facades. The PV device and the array as installed should be durable (e.g. long lasting, sealed against moisture and other environmental conditions) and protected from mechanical abuse over the desired lifetime of the product, preferably at least 15 years, more preferably at least 25 years. The device should be easily installed into the array of devices (e.g. installation similar to conventional roofing shingles or exterior wall coverings) or replaced (e.g. if damaged).

In one exemplary configuration, BIPVs can be configured and installed in a similar fashion to that of traditional building cladding materials (e.g. roofing shingles/tiles or vinyl siding), in rows and columns, and particularly in partially overlapping rows. One well known issue with currently available BIPV systems is that of thermal management. It is believed that current state of the art systems may become less efficient in the creation of electricity if they become too hot, and it may be advantageous to introduce some kind of thermal management features to the BIPVs. It may also be advantageous to utilize any heat created by the BIPV systems for other uses, such as heating the structure, especially in colder climates.

Among the literature that can pertain to this technology include the following patent documents: WO/2009/137353A3; WO/2009/137352A3; WO/2009/137348A3; and WO/2009/1373417A3; all incorporated herein by reference for all purposes and particularly for teachings on photovoltaic roofing or building sheathing element, arrays, and connectors, and U.S. Pat. No. 7,328,534 in regards to thermal venting.

### SUMMARY OF THE INVENTION

The present invention seeks to help solve one or more of the problems/issues disclosed above. The present invention is particularly directed to photovoltaic devices that include one or more improved thermal management features, more particularly to thermal management features that are integral to the BIPV device.

Accordingly, pursuant to one aspect of the present invention, there is contemplated a photovoltaic device for use on a structure, including at least: a. an inactive portion including lower surface portion that directly or indirectly contacts the structure, and an upper surface portion that includes one or more open airflow conduits and a fastener region for receiving one or more fasteners capable of securing the photovoltaic device directly to the structure; and b. an active portion including a photovoltaic cell assembly; wherein the active portion and the inactive portion are coupled on at least one peripheral edge and the one or more conduit structures in the upper surface portion of the inactive portion is in fluid communication with a portion of a bottom surface of the active portion.

The invention may be further characterized by one term any combination of the features described herein, such as the inactive portion comprises a molded polymeric material and the active portion comprises a multilayered laminate; the molded polymeric material frames one or more of the peripheral edges of the multilayered laminate; the device is in electrical communication with a control unit and a thermostat; the photovoltaic device includes one or more air moving devices in fluid communication with the one or more conduit structures; a height of the inactive portion of the device is at least equal to a height of the active portion; and the one or more conduit structures have a vertical thickness that is equal to or less than a vertical thickness of one or more electrical connectors.

Accordingly, pursuant to another aspect of the present invention, there is contemplated an assembly of photovoltaic devices on a structure, including at least one or more photovoltaic devices configured in two or more vertically overlapping rows, the one or more photovoltaic devices comprising: a. an inactive portion including lower surface portion that directly or indirectly contacts the structure, and an upper surface portion that includes one or more conduit structures and a fastener region for receiving one or more fasteners capable of securing the photovoltaic device directly to the structure; and b. an active portion including a photovoltaic cell assembly; wherein the active portion and the inactive portion are coupled on at least one peripheral edge and the one or more conduit structures in the upper surface portion of the inactive portion is in fluid communication with a portion of a bottom surface of the active portion; wherein the active portion of an upper row overlaps at least one or more open airflow conduits of the inactive portion of a lower row forming a dosed airflow channel therebetween.

The invention may be further characterized by one or any combination of the features described herein, such as the inactive portion comprises a molded polymeric material and the active portion is a multilayered laminate the molded polymeric material frames one or more of the peripheral edges of the multilayered laminate; the one or more conduit structures have a vertical thickness that is equal to or less than a vertical thickness of one or more electrical connectors; the photovoltaic device includes one or more air moving devices in fluid communication with the one or more conduit structures; a height of the inactive portion of the device is at least equal to a height of the active portion; the structure includes one or more air moving devices in fluid communication with the one or more conduit structures; comprising one or more air ports on or through the structure in fluid communication with the open air flow conduits of the inactive portion of the photovoltaic devices; one or more of the air ports communicate with one or more fluid ducts disposed in the structure to more air into or out of the structure; one or more air ports can be intake air ports, exhaust air ports or both; the one or more air ports comprise one or more intake air ports and one or more exhaust air ports; one or more switching devices are located in or between fluid ducts to control the flow and direction of flow of air the system; one or more switching devices are located in or between fluid ducts to control the flow and direction of flow of air in the system; and one or more devices are in electrical communication with a control unit and a thermostat.

### DESCRIPTION OF THE DRAWINGS

FIG. 1 illustrates array of photovoltaic devices of the invention on a building structure.

FIG. 2A illustrates the layers of an embodiment of a photovoltaic device of the invention in an exploded view.

FIG. 2B illustrates the layers of an embodiment of a photovoltaic device of the invention in an exploded view.

FIG. 3 illustrates an array of the photovoltaic devices of the invention on a building structure comprising 6 rows.

FIG. 4A illustrates a cut away view of an interface member adjoining standard building sheathing member.

FIG. 4B illustrates another embodiment of an interface member adjoining a standard building sheathing member.

FIG. 4C illustrates yet another embodiment of an interface member adjoining a standard building sheathing member.

FIG. 5 illustrates yet another embodiment an interface member adjoining a standard building sheathing member.

FIG. 6 illustrates an interface member in a role form.

FIG. 7A illustrates a top view of a photovoltaic device sheathing device showing thermal management features.

FIG. 7B illustrates a cut away view along line B-B of the device of FIG. 7A.

FIG. 7C illustrates a cut away view along line C-C of the device of FIG. 7A.

FIG. 7D illustrates a cut away view along line D-D of the device of FIG. 7A.

FIG. 7E illustrates another embodiment of a photovoltaic device of the invention.

FIG. 8A illustrates an array of the photovoltaic devices of the invention on a building structure.

FIG. 8B illustrates a cut-away view of the array of FIG. 8A along line A-A.

FIG. 9A illustrates a cut-away view of an array wherein the air conduits of the array are in fluid communication with an air port in the roof having a fan in an associated fluid duct.

FIG. 9B illustrates a cut-away view of an array of photovoltaic devices wherein the air conduits are in fluid communication with two air ports, one for fluid intake and one for fluid exhaust.

FIG. 9C illustrates another embodiment of a cut-away view of an array of photovoltaic devices wherein the air conduits are in fluid communication with two air ports, one for fluid intake and one for fluid exhaust.

FIG. 10A illustrates another embodiment of a cut-away view of an array of photovoltaic devices wherein the an conduits are in fluid communication with two air ports, one for fluid intake and one for fluid exhaust.

FIG. 10B illustrates another embodiment of a cut-away view of an array of photovoltaic devices wherein the air conduits are in fluid communication with two an ports, one for fluid intake and one for fluid exhaust and switching devices are located in the fluid ducts.

### DETAILED DESCRIPTION OF THE PREFERRED EMBODIMENT

Simply stated, the present invention is an improved BIPV with one or more thermal management feature and method of assembly thereof. Each component of the system may be described in further detail in the following paragraphs, in the drawings, or in the other patent applications that are incorporated by reference herein for the purposes stated.

It should be appreciated that the above referenced aspects and examples are non-limiting, as others exist within the present invention, as shown and described herein.

### Photovoltaic Roofing or Building Sheathing Element/Device 100

It is contemplated that the PV sheathing device 100 may be a PV device “P”, or spacer device “S”, or edge pieces “E”, for example as described and disclosed in PCT publication 2009/137353 and corresponding U.S. patent application Ser. No. 12/989743, incorporated herein by reference for the teachings of the structure of the photovoltaic device and the filler piece (AKA spacer devices “S”).

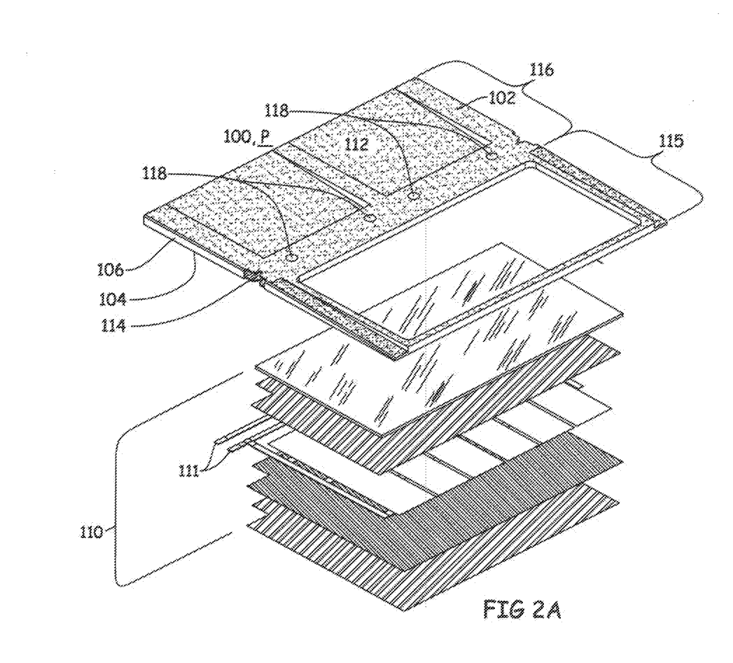

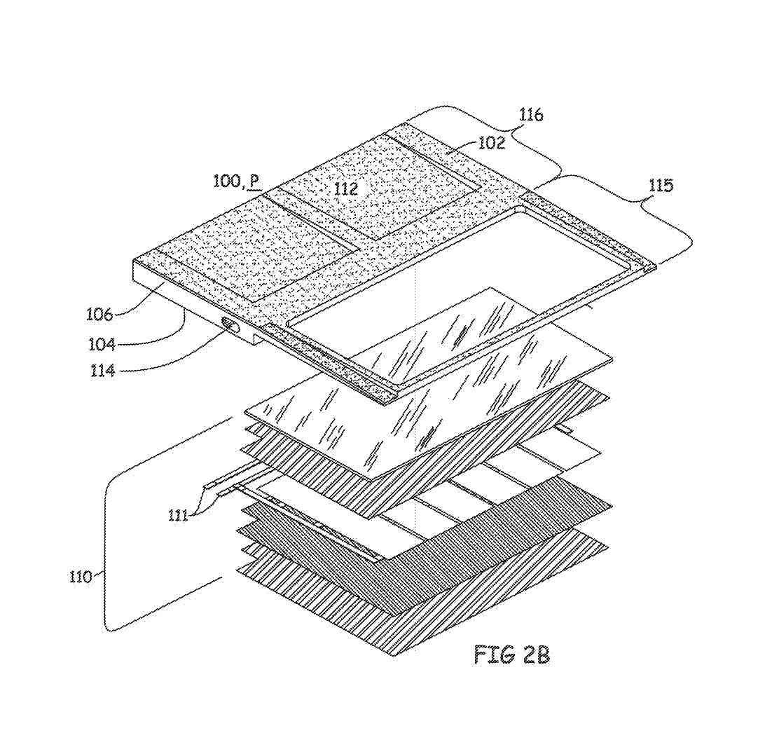

A PV device “P” functions as an electrical generating device that includes a functional element such as a photovoltaic cell assembly 111 within its structure. One illustrative example of a PV device “P” may be seen in FIGS. 2A and 2B (wherein 2B shows a significantly thicker inactive portion), where an exploded view of a device “P” is shown. This illustrative example shows a device “P” that is constructed of a multilayered laminate 110 that is surrounded (e.g. via over-molding) by a body portion 112. It may also be described as a device “P” that includes an active portion 115 and are inactive portion 116, wherein the inactive 110 portion frames at least a portion of the peripheral edge of the active portion 115. Another possible way to describe the active and inactive portions 115, 116 is that generally, the active portion 115 is visible and exposed when installed on a building and the inactive portion 116 generally is not visible or exposed. The device may also be described as having one or more fastening locations 118, which generally are disposed in the inactive portion 116 and may be marked graphically or textually.

An edge piece “E” generally functions to connect multiple rows of devices together, and may or may not include other functional elements. The edge piece “E” also may serve as an interface between the side of the array 1000 and any adjoining materials (e.g. standard roofing/sheathing materials). A spacer device “S” generally may function to connect devices within a row, and may or may not include other functional elements.

The device 100 whether in the form of a PV device “P”, a spacer device “S”, or edge pieces “E”, can be further defined as having a top surface 102, a bottom surface 104 and a peripheral edge 106 spanning therebetween. It is also contemplated that the device 100 has an electrical connector (e.g. sheathing device electrical connector 114) disposed on or about the peripheral edge 106 that provides the junction for electrical energy produced by the device for the array). In a preferred embodiment, the peripheral edge 106 is no more than about 35 mm in thickness, more preferably no more than about 25 mm, most preferably about 20 mm, and no thinner than about 5 mm, more preferably no thinner than about 10 mm, and most preferably no thinner than about 15 mm. When viewed from an active portion 115 and inactive portion 116 standpoint, peripheral edge 106 may also be defined by the height of the active portion and the height of the inactive portion, respectively. It is contemplated that in certain areas, for example on an edge piece “E”, where standard roofing/sheathing materials may be overlaid, the peripheral edge 106 may be as thin as 0.5 mm. Additionally, in the case of a spacer device “S” or edge piece “E” and for the purposes of this invention, the inactive portion 116 is generally considered that part of the device that is co-extensive with and/or above the sheathing device electrical connector 114.

The device 100 may also include one or more conduit structures 150 in the inactive portion 116 that may be adapted to provide a portion of the structure that creates one particular thermal management feature 250 (e.g. air conduit). A more detailed explanation and illustrative examples of the thermal management feature(s) 250 are provided in a separate section below.

It is preferred that the devices 100 are constructed primarily of a polymer (not including any functional elements such as the photovoltaic cells), although metallic materials are possible, Preferred materials or combinations of materials include a filled or unfilled moldable plastic (e.g. polyolefins, acrylonitrile butadiene styrene, hydrogenated styrene butadiene rubbers, polyester amides, polysulfone, acetel, acrylic, polyvinyl chloride, nylon, polyethylene terephthalate, polycarbonate, thermoplastic and thermoset polyurethanes, synthetic and natural rubbers, epoxies styrene-acrylonitrile (“SAN”), polymethyl methacrylate, polystyrene, Of any combination thereof). Fillers can include one or more of the following: colorants, fire retardant (“FR”) or ignition resistant (“IR”) materials, reinforcing materials, such as glass or mineral fibers, mineral fillers, such as talc, calcium carbonate or mica, or surface modifiers. Plastic can also include anti-oxidants, release agents, blowing agents, and other common plastic additives.

The photovoltaic cell assembly 111 may comprise photovoltaic cells that are constructed of any material known to provide that function may be used including crystalline silicon, amorphous silicon, CdTe, GaAs, dye-sensitized solar cells (so-called Gratezel cells), organic/polymer solar cells, or any other material that converts sunlight into electricity via the photoelectric effect. However, the photoactive layer is preferably a layer of IB-IIIA-chalcogenide, such as IB-IIIA-selenides, IB-IIIA-sulfides, or IB-IIIA-selenide sulfides. More specific examples include copper indium selenides, copper indium gallium selenides, copper gallium selenides, copper indium sulfides, copper indium gallium sulfides, copper gallium selenides, copper indium sulfide selenides, copper gallium sulfide selenides, and copper indium gallium sulfide selenides (all of which are referred to herein as CIGSS). These can also be represented by the formula CuIn(1−x)GaxSe(2−y)Sy where x is 0 to 1 and y is 0 to 2. The copper indium selenides and copper indium gallium selenides are preferred. Additional electroactive layers such as one or more of emitter (buffer) layers, conductive layers (e.g. transparent conductive layers) and the like as is known in the art to be useful in CIGSS based cells are also contemplated herein. These cells may be flexible or rigid and come in a variety of shapes and sizes, but generally are fragile and subject to environmental degradation. In a preferred embodiment, the photovoltaic cell assembly 111 is a cell that can bend without substantial cracking and/or without significant loss of functionality. Exemplary photovoltaic cells are taught and described in a number of US patents and publications, including U.S. Pat. No. 3,767,471, U.S. Pat. No. 4,465,575, US20050011550 A1, EP841706 A2, US20070256734 a1, EP1032051A2, JP2216874, JP2143468, and JP10189924a, incorporated hereto by reference for all purposes.

### Array of Devices/Elements 1000

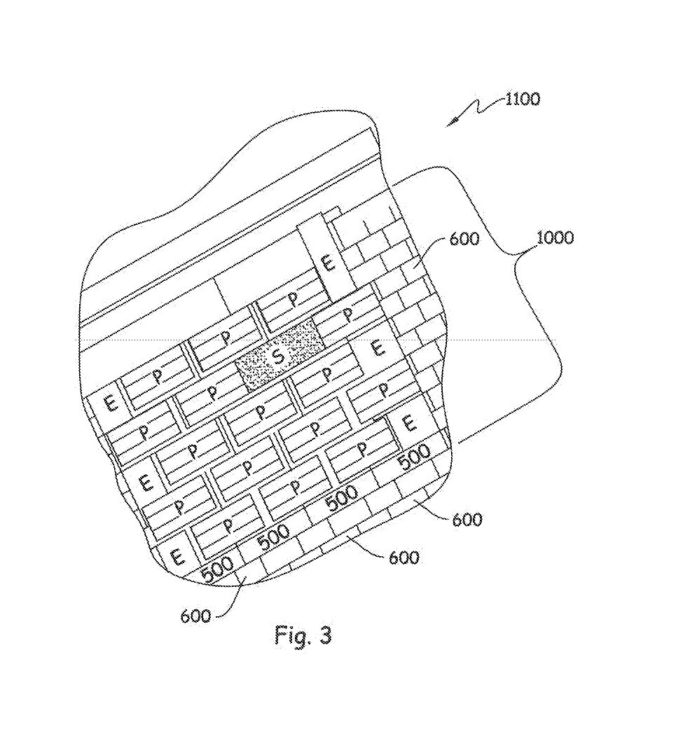

An array of devices (e.g. PV device “P”, spacer devices “S”, edge pieces “E”, etc.) function to provide electrical energy when subjected to solar radiation (e.g. sunlight). An array is a collection of interconnected devices as installed on a building structure 1100. For the purposes of this invention, it is contemplated that the array 1000 is installed directly on an existing roof structure (or exterior surface) of a building structure 1100, over a roofing underlayment material (felt self-adhered water barrier, fire-retardant layer, or moisture barrier sheet), or over a previously installed roofing material (e.g. asphalt shingles), in the same way traditional roofing elements are applied (unless otherwise noted herein). In a preferred embodiment, these arrays 1000 may be made up of two or mare rows of adjoining devices, the rows containing at least two or more devices themselves. One or more interface members 500, described in more detail below, may be disposed on the bottom of the array 1000. As an illustrative example, at least partially shown in FIG. 3, the array 1000 presented has 6 rows, multiple devices per row including an edge piece on each end and one exemplary illustration of interface members 500 making up the bottom row of the array (row 6). The focus of this invention is how thermal management feature 250 may resolve one or more of the problems/issues previously discussed.

### Interface Members 500

An interface member 500 function to provide an interface row between the PV sheathing devices 100 and any non-PV sheathing device cladding materials (e.g. traditional asphalt shingles, premium roofing material such as concrete tile or natural slate, or similar components, herein referred to as a “sheathing member” 600). The member or members 500 may provide a nesting portion for both the PV sheathing devices 100 and for the sheathing member 600. It is contemplated that the member may allow for the installation/removal of devices 100 and/or members 600 independently of each other and in any order.

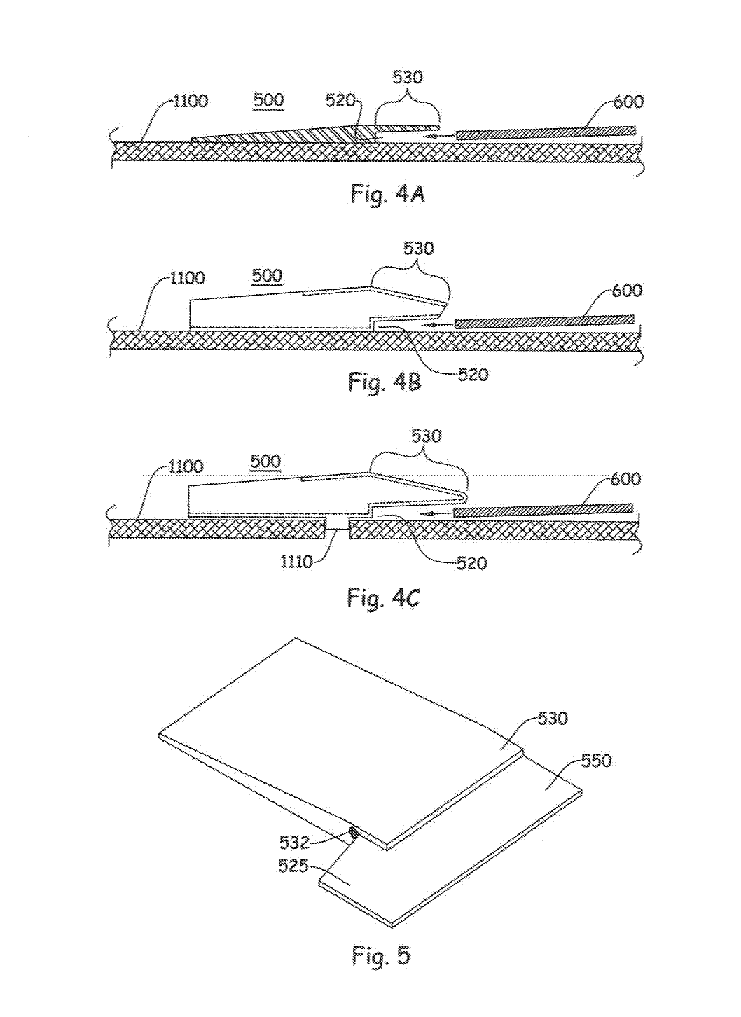

It is contemplated that the interface member 500 may at least be a three dimensional component that includes a PV sheathing element nesting portion 510 and a building sheathing nesting portion 520. Exemplary embodiments and variations are discussed in detail below. The PV sheathing element nesting portion 510 functions as a receiving area for the devices 100, wherein typically the device sits on top of the nesting portion in the installed position. It is contemplated that the nesting portion may include positioning features that aid in locating the devices. The building sheathing nesting portion 520 functions as at least receiving area for the sheathing members 600, wherein the member 600 at least abuts the nesting portion, for example as shown in FIGS. 4A-C. It is also contemplated that the member 500 may include horizontal overlap portions 525 and a living hinge 532, for example as shown in FIG. 5, which function to provide an interface/overlap area between the side of the member and horizontally adjoining sheathing members 600.

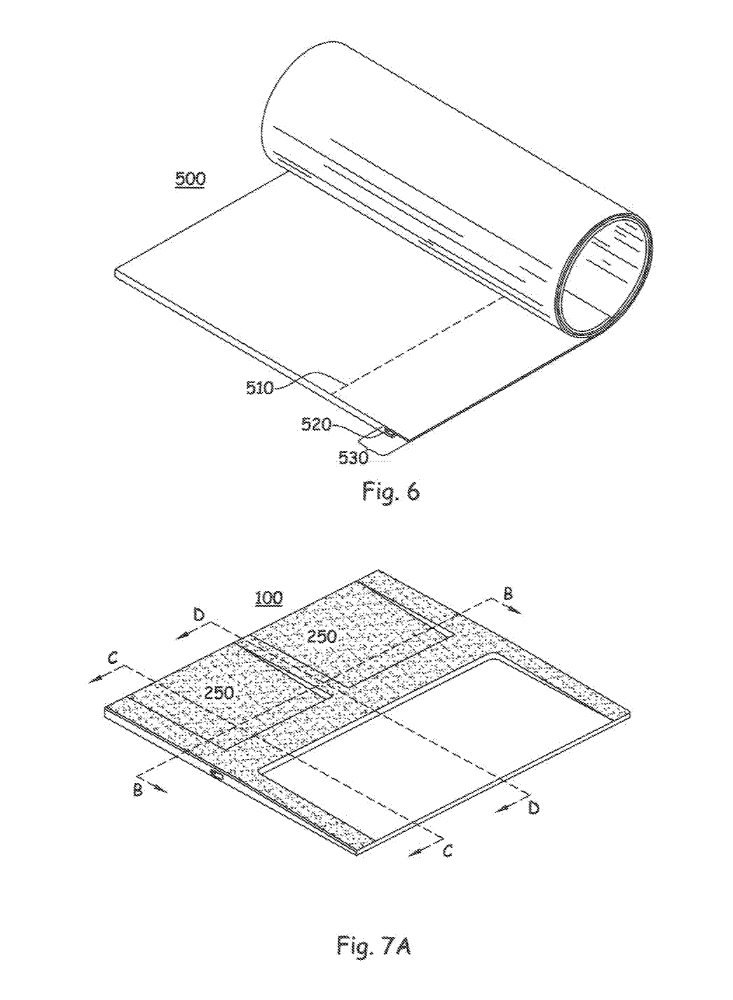

It is contempt ted that the interface member 500 may be in the form of a discrete component (e.g. a panel-like member akin to devices 100) or may be in a continuous roll form, for example as shown in FIGS. 4 and 6 respectively.

In a preferred embodiment, the member 500 is constructed essentially of a polymeric material. Preferred materials or combinations of materials include a filled or unfilled moldable plastic (e.g. polyolefins acrylonitrile butadiene styrene, hydrogenated styrene butadiene rubbers, polyester amides, polysulfone, acetol, acrylic, polyvinyl chloride, nylon, polyethylene terephthalate, polycarbonate, thermoplastic and thermoset polyurethanes, synthetic and natural rubbers, epoxies, styrene-acrylonitrile (“SAN”), polymethyl methacrylate, polystyrene, or any combination thereof). Fillers can include one or more of the following: colorants, fire retardant (“FR”) or ignition resistant (“IR”) materials, reinforcing materials, such as glass or mineral fibers, mineral filters, such as talc, calcium carbonate or mica, or surface modifiers. Plastic can also include anti-oxidants, release agents, blowing agents and other common plastic additives.

In the case where the member 500 is in a continuous roll form, for example as shown in FIG. 6, the preferred materials include: Polyolefins; hydrogenated styrene butadiene rubber polyesters; polyamides; polyesteramides; poly (vinyl chloride); synthetic and natural rubbers; EPDM; and asphalt type compounds (i.e., shingle like material). A preferred embodiment can also be further defined as wherein X=(thickness in mm)̂2/(ultimate strain in percent), X is less than about 200, more preferably less than 50, most preferably less than 10 and/or wherein Y=(Modulus of elasticity in MPa+thickness in mm), Y is less than about 20,000, more preferably less than 4,000, most preferably less than 1,000.

### Thermal Management Feature 250

It is contemplated that the device 100 may include one or more thermal management features 250 (e.g. for example as shown in FIGS. 2A-B and 7A-D). The thermal management feature 250 functions as a mechanism for providing some level of thermal control for a device 100, either passively (e.g. via convection) or actively (with an air moving device 280, e.g. a small fan preferably powered by the device 100). Thermal control, at least as it relates to the present invention is contemplated to be the ability to maintain a relatively low differential in temperature between the area under the active portion 115 and the outside environment, as installed on a structure, for example a differential of less than about 15° C. Optionally, the one or more thermal management features 250 may also serve to provide a conduit for heat energy for other various functions.

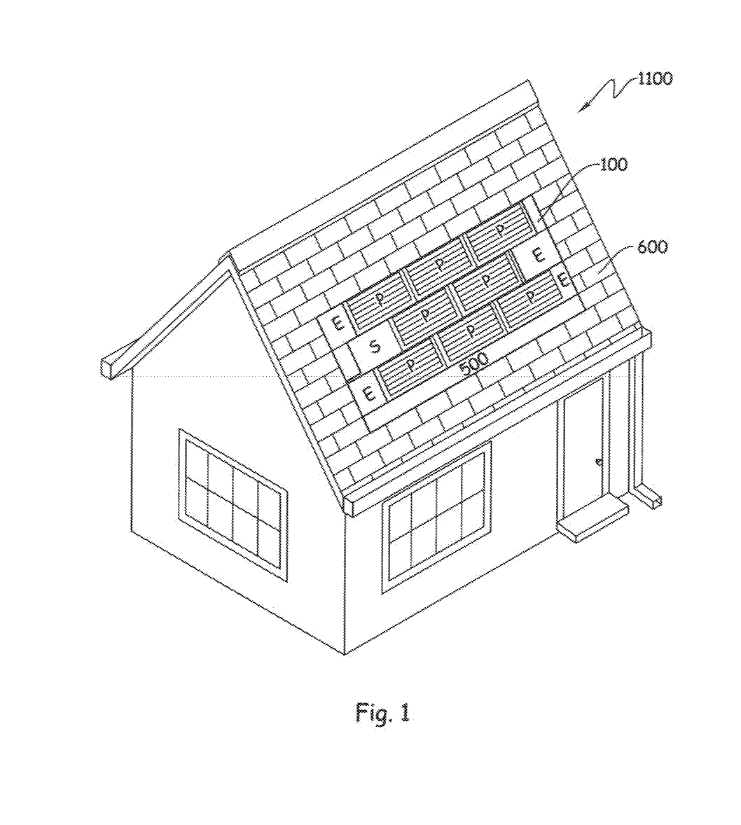

It is contemplated that the inactive portion of the device 100 included at least one or more conduit structures 150 and one or more through holes 270 that allow air to be communicated between a portion of the top surface 102 of the inactive portion 116 and the underside of the active portion 115. It is contemplated that when a second device 100 (or similar covering) is placed over the inactive portion (e.g. as would be as assembled to the building structure 1100 in an array 1000) the conduit structure 150 becomes essentially a closed chamber (dimensionally with a thickness or height CS_{T} and a width CS_{W}). It is contemplated that when components (devices 100) of the array 1000 are assembled to a structure 1100 (e.g. as shown in FIGS. 1 and 3), the thermal management feature 250 may provide a path for airflow that spans from the bottom of the array 1000 (e.g. row no 6, FIG. 3) to the top (e.g. row 1, FIG. 3). It is also contemplated that there may be a plurality of entry and exit points (e.g. air ports) for the airflow, depending upon the desired configuration. It is contemplated that these airports may be fluidly connected to the structure 1100 or independent thereof. Several examples are provided below. These examples should riot be considered limiting and are for illustrative purposes.

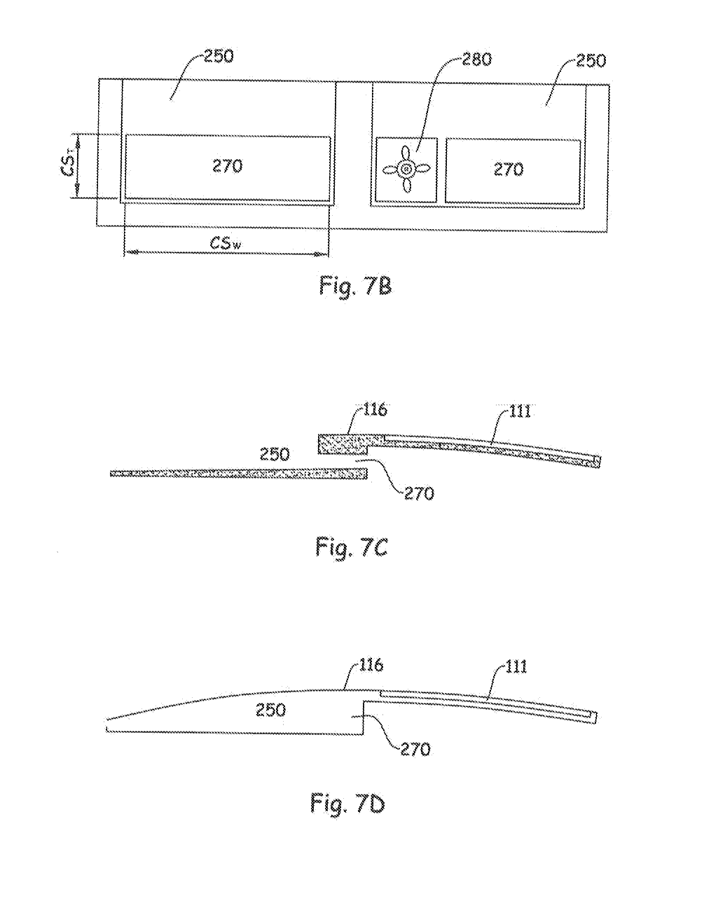

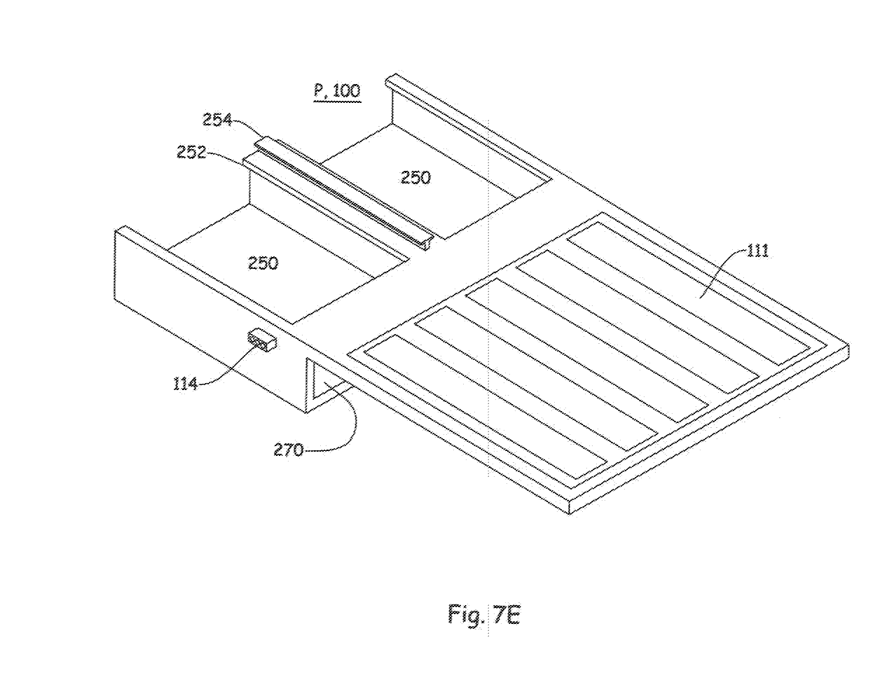

The one or more conduit structures 150, at least in one embodiment, may have a vertical thickness CS_{T} that is equal to or less than a vertical thickness of one or more sheathing device electrical connector 114 as a maximum (“vertical” being defined as a direction perpendicular to the top surface 102 and the bottom surface 104). In another embodiment, for example as seen in FIGS. 2B and 7D, vertical thickness CS_{T} may be considerably larger than a vertical thickness of one or more sheathing device electrical connector 114 (“vertical” being defined as a direction perpendicular to the top surface 102 and the bottom surface 104). This may be preferred if a larger volume of air flow is desired, The inactive portion 116 may also contain features to capture or seal the edges of the overlapping active regions 115. For example, features 252 and 254 as illustrated FIG. 7D may also aid in locating subsequent rows, securing of the active portion on subsequent rows during wind loading, limiting or prevent water ingress, and/or preventing air leakage from or into the conduit structure. When assembled into an array, the example shown in FIG. 7D may capture both sides of the active portion of the subsequent row. Similarly, these features could also be included on the lower edge to capture three edges of the active region or they may be included on a single edge. Feature 252 projects upward from the inactive region to provide sealing. This may be combined with a water directing or channeling feature. Feature 254 captures the edge of the next row for compressions against 252 and wind uplift. In a similar way, a hook or lip could be used to catch the lower edge of the next row. It is contemplated that these areas may also include sealing aids in the form of adhesives, caulks, or other materials to aid in preventing exchange of gases or liquids between the thermal management conduit and the exterior environment.

It is also contemplated that the minimum thickness be defined in terms of a cross-sectional area CS_{A} (CS_{A}=CS_{T}*CS_{W}). The CS_{A} being sufficiently large as to allow for convective air flow through the conduit structures 150 when a temperature differential of at least about 5° C. exists between the area under active portion 115 and the environment outside or the devices. CS_{T} is greater than about 4 mm, more preferably is greater than about 8 mm, even more preferably greater than about 15 mm, and preferably less than about 180 mm, more preferably less than about 140 mm and most preferably less than about 100 mm. Wherein CS_{W} is equal to or less than the width of the PVD (e.g.) as shown in the drawings on the through holes 270 in FIG. 7B). In the case where one or more air movers 280 are utilized in the thermal management features 250, it is contemplated that the CS_{T} may be considerably less, as much as about 50% less than the preferred values stated above.

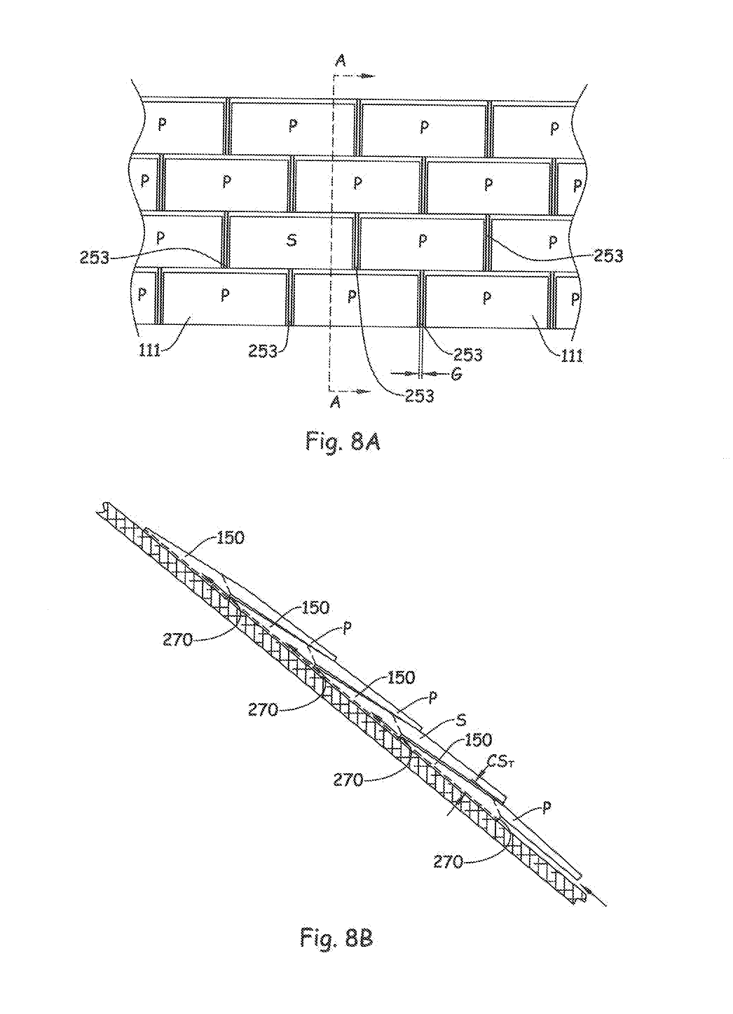

In a first illustrative example, as shown in FIGS. 8A and 8B, an assembly of devices is shown in 4 rows. In this example, the second row includes a spacer “S” for one of the devices 100. For the sake of the present invention, the “active portion” of the spacer is the area which is primarily visible when installed and by definition does not require the photovoltaic cell assembly to be covered by the claims herein. In this example, as shown in FIG. 8B, the assembly is disposed on the structure 1100. It is contemplated that air can enter (e.g. via air ports) the thermal management feature 250 via the gap “G” between devices in a row or under the front of the devices (as shown in FIG. 8A), air flow designated by the arrows →. In this illustrative example, the air ports as shown are independent of the building structure 1100.

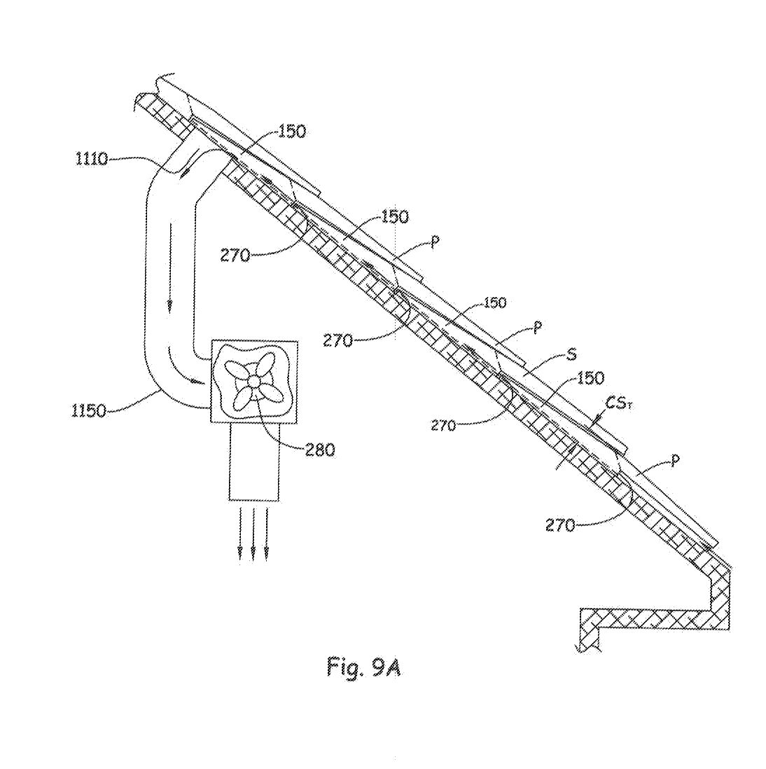

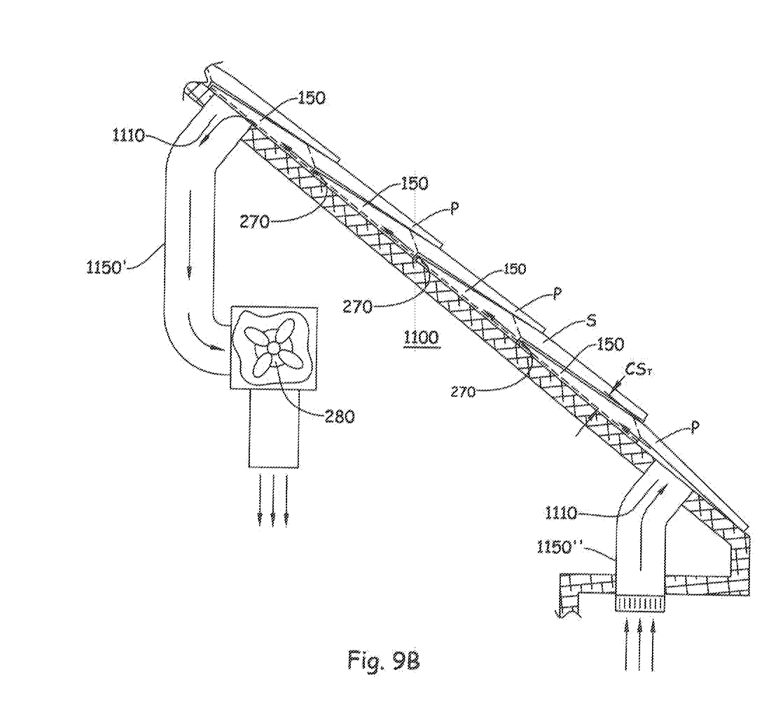

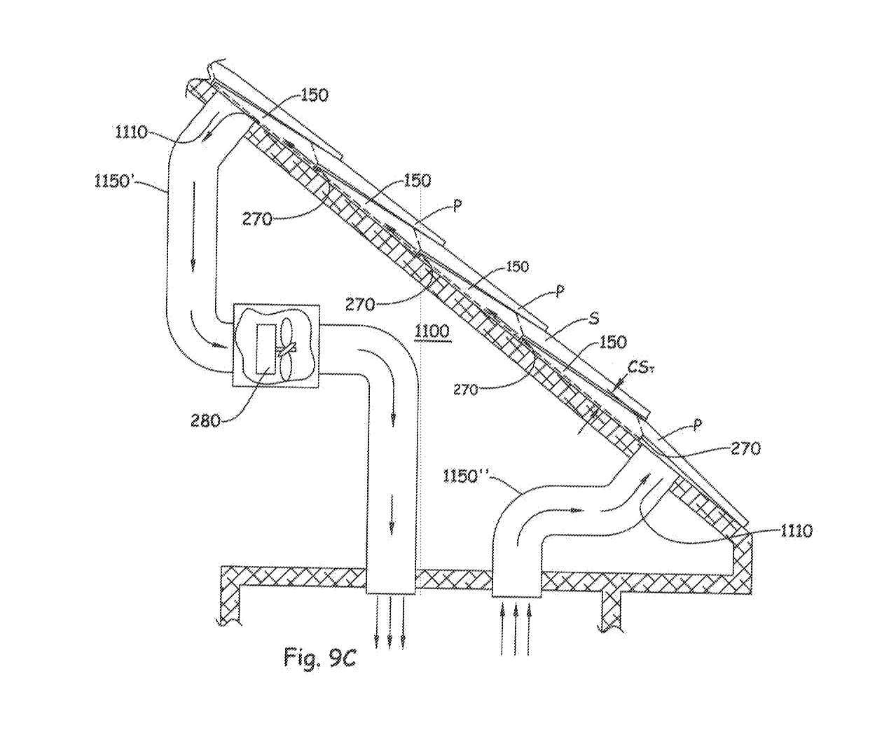

In a second illustrative example, as shown in FIGS. 9A through 9C, one or more air ports 1110 are disposed on (or through) the structure 1100 and are in fluid communication with the thermal management feature 250. It is contemplated that the movement of the air through the system may be aided with the use of an air mover (e.g. fan) 280, in this case located within the structure 1100. The air ports 1110 may be in communicatin with one or more fluid ducts 1150 in the structure. The fluid ducts 1150 may be intake ducts or exhaust ducts. A single duct may perform both function or two or more ducts may be set up so that at least one is an intake duct and at least one is an exhaust duct.

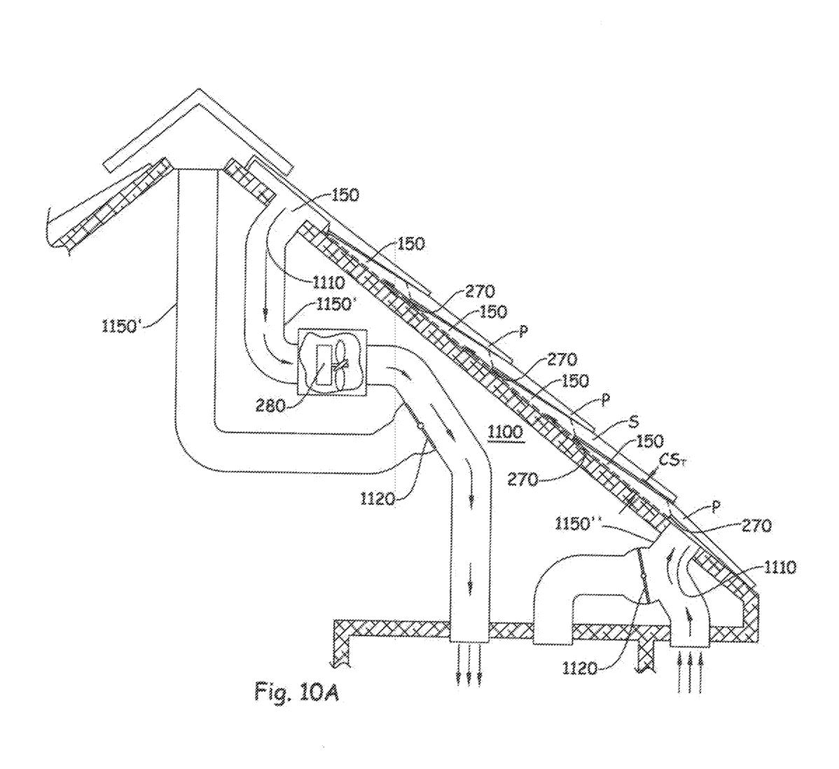

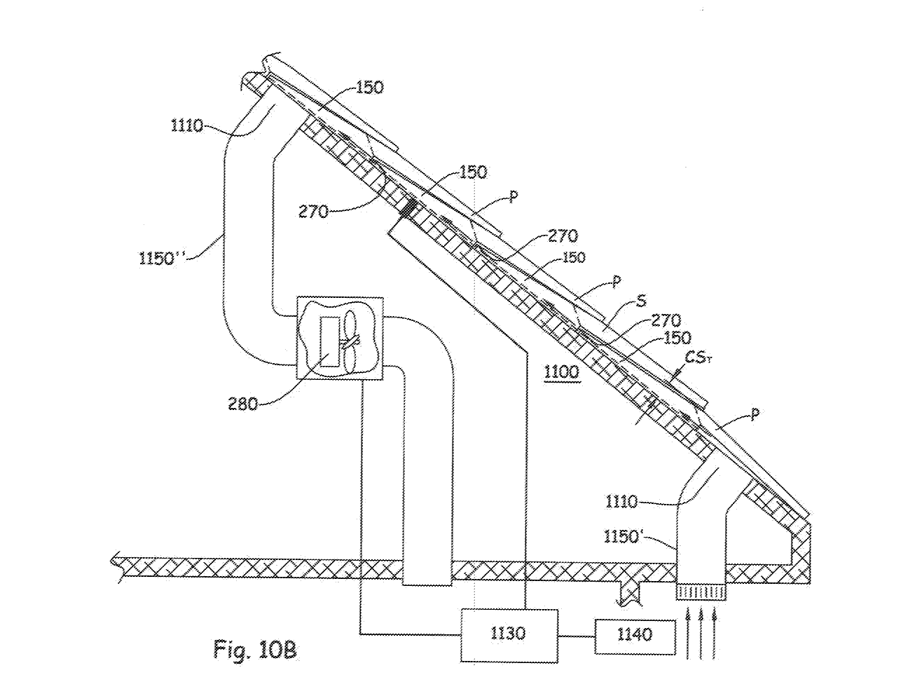

In a third illustrative example, as in FIGS. 10A and 10B, the thermal management feature 250 includes one or more switching devices 1120 in fluid communication with the thermal management feature 250. The one or more switching devices 1120 may be integrated into the building structure 1100 and may function, for example, to pull hot air into the structure on cold days and divert hot air out on warm days utilizing the fluid ducts. The switching devices 1120 may be disposed in an air duct. In FIG. 10B, a control unit 1130 and a thermostat 1140 is schematically shown. It is contemplated that the control unit in conjunction with the thermostat functions to control the activation of the air mover(s) 280, the switching device(s) 1120, or both. It is also contemplated that there may be other thermostats 1140 disposed within the array 1000 (e.g. on the exterior surface and/or in the channel 150). These thermostats may provide data (input) to the controller 1130 concerning the temperatures at other locations and may be part of a control algorithm, for example to determine the desired position of the switching devices/air movers due to the temperature differential as discussed previously. In FIGS. 10 A and 10 B intake fluid ducts 1150′ and exhaust fluid ducts 1150″ are illustrated.

It is contemplated and expressly stated heroin that the embodiments or examples described above may not be mutually exclusive and may be used in combination with each other.

Unless stated otherwise, dimensions and geometries of the various structures depicted herein are not intended to be restrictive of the invention, and other dimensions or geometries are possible. Plural structural components can be provided by a single integrated structure. Alternatively, a single integrated structure might be divided into separate plural components. In addition, while a feature of the present invention may have been described in the context of only one of the illustrated embodiments, such feature may be combined with one or more other features of other embodiments, for any given application. It will also be appreciated from the above that the fabrication of the unique structures herein and the operation thereof also constitute methods in accordance with the present invention.

The preferred embodiment of the present invention has been disclosed. A person of ordinary skill in the art would realize however, that certain modifications would come within the teachings of this invention. Therefore, the following claims should be studied to determine the true scope and content of the invention.

Any numerical values recited in the above application include all values from the lower value to the upper value in increments of one unit provided that there is a separation of at least 2 units between any lower value and any higher value. As an example, if it is stated that the amount of a component or a value of a process variable such as, as for example, temperature, pressure, time and the like is, for example, from 1 to 90, preferably from 20 to 80, more preferably from 30 to 70, it is intended that values such as 15 to 85, 22 to 68, 43 to 51, 30 to 32 etc. are expressly enumerated in this specification. For values which are less than one, one unit is considered to be 0.0001, 0.001, 0.01 or 0.1 as appropriate. These are only examples of what is specifically tended and all possible combinations of numerical values between the lowest value and the highest value enumerated are to be considered to be expressly stated in this application in a similar manner.

Unless otherwise stated, all ranges include both endpoints and all numbers between the endpoints, The use of “about” or “approximately” in connection with a range applies to both ends of the range. Thus, “about 20 to 30” is intended to cover “about 20 to about 30”, inclusive of at least the specified endpoints.

The disclosures of all articles and references, including patent applications and publications, are incorporated by reference for all purposes.

The term “consisting essentially or” to describe a combination shall include the elements, ingredients, components or steps identified, and such other elements ingredients, components or steps that do not materially affect, the basic and novel characteristics of the combination.

The use of the terms “comprising” or “including” describing combinations of elements, ingredients, components or steps herein also contemplates embodiments that consist essentially of the elements, ingredients, components or steps.

Plural elements, ingredients, components or steps can be provided by a single, integrated element, ingredient, component or step. Alternatively, a single integrated element, ingredient, component or step might be divided into separate plural elements, ingredients, components or steps. The disclosure of “a” or “one” to describe an element, ingredient, component or step is not intended to foreclose additional elements, ingredients, components or steps. All references herein to elements or metals belonging to a certain Group refer to the Periodic Table of the Elements published and copyrighted by CRC Press, Inc., 1989. Any reference to the Group or Groups shall be to the Group or Groups as reflected in this Periodic Table of the Elements using the IUPAC system for numbering groups.

1. A photovoltaic device for use on a structure, comprising:
a. an inactive portion including lower surface portion that directly or indirectly contacts the structure, and an upper surface portion that includes one or more open airflow conduits and a fastener region for receiving one or more fasteners capable of securing the photovoltaic device directly to the structure; and
b. an active portion including a photovoltaic cell assembly;
wherein the active portion and the inactive portion are coupled on at least one peripheral edge and the one or more conduit structures in the upper surface portion of the inactive portion and one or more through holes in the inactive portion are in fluid communication with a portion of a bottom surface of the active portion wherein the conduit structure of the inactive portion forms a closed chamber when the active portion of another overlapping device is placed over the inactive portion and the active portion forms a closed chamber when placed over the inactive portion of another device or an interface member wherein the through holes communicate between the closed chambers formed.

2. The photovoltaic device according to claim 1, wherein the inactive portion comprises a molded polymeric material and the active portion comprises a multilayered laminate.

3. The photovoltaic device according to claim 2, wherein the molded polymeric material frames one or more of the peripheral edges of the multilayered laminate.

4. The photovoltaic device according to claim 1, wherein the device is in electrical communication with a control unit and a thermostat to control switching devices or air movers to adjust the flow of air in or out of a building.

5. The photovoltaic device according to claim 1, wherein the photovoltaic device includes one or more air moving devices in fluid communication with the one or more conduit structures.

6. The photovoltaic device according to claim 1, wherein a height of the inactive portion of the device is at least equal to a height of the active portion.

7. The photovoltaic device according to claims according to claim 1 wherein the one or more conduit structures have a vertical thickness that is equal to or less than a vertical thickness of one or more electrical connectors.

8. An assembly of photovoltaic devices on a structure, comprising: one or more photovoltaic devices according to claim 1 configured in two or more vertically overlapping rows, wherein the active portion of an upper row overlaps at least one or more open airflow conduits of the inactive portion of a lower row forming a closed airflow channel therebetween.

9. The assembly according to claim 8 further comprising one or more air ports on or through the structure in fluid communication with the open air flow conduits of the inactive portion of the photovoltaic devices.

10. The assembly according to claim 9 wherein one or more of the air ports communicate with one or more fluid ducts disposed in the structure to move air into or out of the structure.

11. The assembly according to claim 9 wherein the one or more air ports can be intake air ports, exhaust air ports or both.

12. The assembly according to claim 9 wherein the one or more air ports comprise one or more intake air ports and one or more exhaust air ports.

13. The assembly according to claim 8 wherein one or more switching devices are located in or between fluid ducts to control the flow and direction of flow of air in the system.

14. The assembly according to claim 8, wherein one or more devices are in electrical communication with a control unit and a thermostat.

15. The assembly according to claim 8, wherein the inactive portion comprises a molded polymeric material and the active portion comprises a multilayered laminate.

16. The assembly according to claim 15, wherein the molded polymeric material frames one or more of the peripheral edges of the multilayered laminate.

17. The assembly according to claim 8, wherein the photovoltaic device includes one or more air moving devices in fluid communication with the one or more conduit structures.

18. The assembly according to claim 8, wherein a height of the inactive portion of the device is at least equal to a height of the active portion.

19. The assembly according to claims according to claim 8, wherein the one or more conduit structures have a vertical thickness that is equal to or less than a vertical thickness of one or more electrical connectors.
